(19) United States
(12) Patent Application Publication
(10) Pub. No.: US 2023/0407469 A1
(43) Pub. Date: Dec. 21, 2023

(54) CONTINUOUS ATMOSPHERIC PRESSURE CVD TOW COATER PROCESS WITH IN-SITU AIR LEAK MONITORING

(71) Applicant: Raytheon Technologies Corporation, Farmington, CT (US)

(72) Inventors: Ying She, Rocky Hill, CT (US); John E. Holowczak, South Windsor, CT (US); John J. Walker, Vernon Rockville, CT (US); Steven W. Gronda, Feeding Hills, MA (US)

(73) Assignee: Raytheon Technologies Corporation, Farmington, CT (US)

(21) Appl. No.: 17/843,128

(22) Filed: Jun. 17, 2022

(51) Int. Cl. G01M 3/20; C23C 16/54; C23C 16/44

(52) U.S. Cl. CPC G01M 3/20; C23C 16/545; C23C 16/4408

(57) ABSTRACT

A system for chemical vapor deposition coating of fiber tows includes a coater having a housing having a tow entrance and a tow exit and defining an interior space, the coater further having a process gas inlet and a process gas outlet; at least one of an entrance side marker gas inlet at the tow entrance and an exit side marker gas inlet at the tow exit; and at least one of an entrance side detection probe upstream of the entrance side marker gas inlet, and an exit side detection probe downstream of the exit side marker gas inlet, the at least one entrance side detection probe and exit side detection probe being configured to detect marker gas. A method is also disclosed.

### BACKGROUND

The present disclosure relates to the continuous chemical vapor deposition coating of fiber tows.

A typical process to perform boron nitride (BN) interphase coatings on silicon carbide (SiC) fiber tows is through chemical vapor deposition (CVD) via either a continuous tow coating or batch process. U.S. Pat. No. 5,364,660 discloses the continuous atmospheric pressure CVD coating of fibers in which a single tow or multiple tows are pulled through a cylindrical BN CVD reactor, where reactants are fed into the reactor either via co-feed or counter-feed mode with respect to the tow travel direction, achieving the interphase coatings on the tows. This process is known as an open CVD process, wherein the tow entrance and exit are open to ambient atmosphere. Exhaust from the CVD process can exit to the hood where the tow coater is located. Therefore, this process may generate potential environmental risk and may not meet current environmental, health, and safety (EH&S) standards.

One potential solution to overcome this issue is to add an effluent outlet at the end of the tow coater and to pull a slightly low pressure inside the tow coater through the outlet by a vacuum pump to direct the effluent to a scrubber to neutralize the exhaust. Thus, with this approach, the pressure in the coater is less than the surrounding ambient pressure (P_{coater}<P_{amb}). This creates a different problem, however, in that the slight difference in pressure between the inside of the tow coater and the ambient atmosphere can pull ambient air into the tow coater through the tow entrance and/or exit, thus leading to an unintended oxygen content in the BN coatings, which is undesirable.

### SUMMARY

In one disclosed configuration, a system for chemical vapor deposition coating of fiber tows, comprises a coater comprising a housing having a tow entrance and a tow exit and defining an interior space, the coater further comprising a process gas inlet and a process gas outlet; at least one of an entrance side marker gas inlet at the tow entrance and an exit side marker gas inlet at the tow exit; at least one of an entrance side detection probe upstream of the entrance side marker gas inlet, and an exit side detection probe downstream of the exit side marker gas inlet, the at least one entrance side detection probe and exit side detection probe being configured to detect marker gas.

In one non-limiting configuration, the system further comprises a pump communicated with the interior space of the coater whereby operation of the pump can be adjusted to adjust pressure in the interior space.

In a further non-limiting configuration, the system further comprises a take-off spool for feeding fiber tow to the tow entrance, and a take-up spool for receiving coated fiber tow from the tow exit.

In a still further non-limiting configuration, the system further comprises a source of marker gas communicated with the at least one entrance side marker gas inlet and exit side marker gas inlet.

In another non-limiting configuration, the source of marker gas comprises a source of an inert carrier gas containing a detectable fraction of detectible gas.

In still another non-limiting configuration, the source of marker gas comprises a source of nitrogen gas dosed with helium.

In a further non-limiting configuration, the at least one detection probe comprises a probe configured to detect helium.

In a still further non-limiting configuration, the system further comprises a control unit configured to receive input from the at least one detection probe and, upon receiving input indicating no marker gas detected, configured to operate the coater at a higher pressure in the interior space.

In another non-limiting configuration, the system further comprises a control unit configured to receive input from the at least one detection probe and, upon receiving input indicating no marker gas detected, configured to change operation of the pump to operate the coater at a higher pressure in the interior space.

In still another non-limiting configuration, the system comprises both of the entrance side marker gas inlet and the exit side marker gas inlet, and both of the entrance side marker gas detection probe and the exit side marker gas detection probe.

In another disclosed configuration, a method for chemical vapor deposition coating of fiber tows, comprises feeding a fiber tow to a tow entrance of a coater comprising a housing defining an interior space; feeding a chemical vapor deposition process gas to the coater at a process gas inlet such that fiber tow in the coater is coated to produce coated fiber tow; removing coated fiber tow from a tow exit of the coater; feeding a marker gas to at least one of an entrance side marker gas inlet at the tow entrance and an exit side marker gas inlet at the tow exit; and monitoring at least one of upstream of the entrance side marker gas inlet, and downstream of the exit side marker gas inlet, for presence of marker gas.

In another non-limiting configuration, the method further comprises adjusting pressure in the coater when the monitoring step does not detect marker gas.

In still another non-limiting configuration, the monitoring step comprises positioning at least one marker gas detection probe in the at least one of upstream of the entrance side marker gas inlet and downstream of the exit side marker gas inlet; and further comprising feeding output from the at least one marker gas detection probe to a control unit configured to operate the coater at a higher pressure when the output indicates no detection of marker gas.

In a further non-limiting configuration, a pump is associated with the interior space of the coater, and the control unit is configured to change operation of the pump to operate the coater at a higher pressure.

In a still further non-limiting configuration, the marker gas comprises an inert carrier gas dosed with a detectable amount of marker gas.

In another non-limiting configuration, the carrier gas is nitrogen.

In still another non-limiting configuration, the marker gas is helium.

In a further non-limiting configuration, the method further comprises removing the process gas from the coater at a process gas outlet of the coater.

In a still further non-limiting configuration, the method further comprises feeding process gas from the process gas outlet to a scrubber.

In another non-limiting configuration, the step of feeding the chemical vapor deposition process gas to the coater is carried out such that pressure inside the coater (P_{coater}) less than ambient pressure (P_{ambient}) outside the coater (P_{coater}<P_{ambient}).

The foregoing features and elements may be combined in various combinations without exclusivity, unless expressly indicated otherwise. These features and elements as well as the operation thereof will become more apparent in light of the following description and the accompanying drawings. It should be understood, however, the following description and drawings are intended to be exemplary in nature and non-limiting.

### BRIEF DESCRIPTION OF THE DRAWINGS

Various features will become apparent to those skilled in the art from the following detailed description of the disclosed non-limiting embodiment. The drawings that accompany the detailed description can be briefly described as follows:

FIG. 1 illustrates components of a continuous process as disclosed herein.

FIG. 2 illustrates an enlarged portion of FIG. 1; and

FIG. 3 illustrates a flow chart in the form of block diagrams that schematically illustrate this aspect of the present disclosure.

### DETAILED DESCRIPTION

The present disclosure relates to coating of objects such as fiber tows and the like, and applies broadly to continuous and batch processes. As discussed below, the present disclosure is particularly well suited to processes wherein the ends or other areas of the coater are open to ambient conditions, and therefore is particularly well suited to continuous fiber tow coating processes.

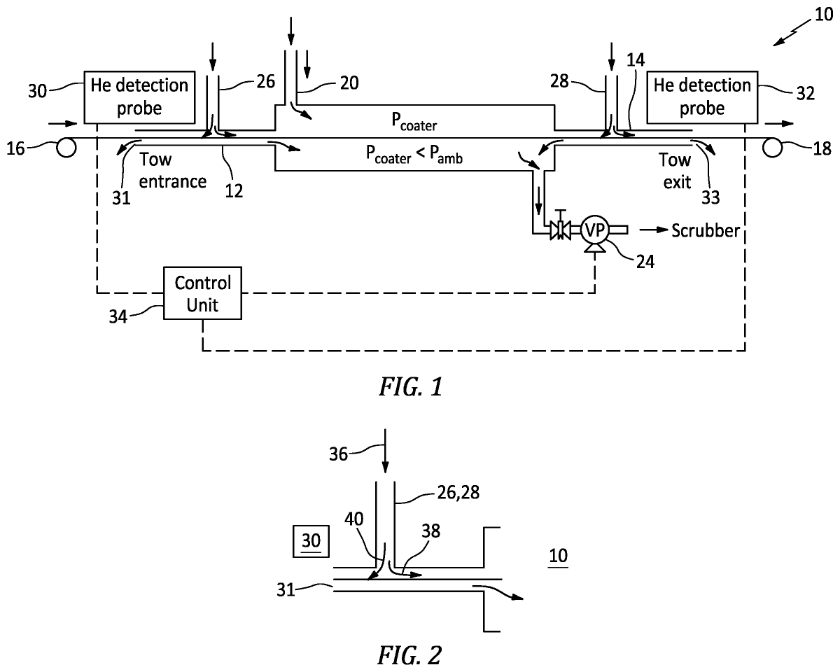

FIG. 1 shows a chemical vapor deposition coater 10 having a tow entrance 12 and a tow exit 14. Fiber tow can be fed from a take-off spool 16 to tow entrance 12, and coated fiber tow leaving the tow exit 14 can be taken up on a take-up spool 18. In FIG. 1, fiber tow passes through the open end at tow entrance 12 of coater 10, is coated within coater 10 to produce coated fiber tow, and coated fiber tow passes through the open end at tow exit 14.

Process gas for conducting the chemical vapor deposition (CVD) coating is fed to a process gas inlet 20, and can be removed from a process gas outlet 22, for example under operation of a vacuum pump 24.

An inlet side marker gas inlet 26 can be positioned at the tow entrance 12 of coater 10. Further, an exit side marker gas inlet 28 can be positioned at the tow exit 14 of coater 10.

An inlet side detection probe 30 can be positioned upstream of inlet side marker gas inlet 26, and an exit side detection probe 32 can be positioned downstream of exit side marker gas inlet 28. Upstream and downstream as used with respect to the positioning of probes 30, 32 is with respect to the intended direction of flow at tow entrance 12 and tow exit 14. In the non-limiting configuration of FIG. 1, the upstream positioning of inlet side detection probe 30 means that probe 30 is positioned away from coater 10 with respect to marker gas inlet 26. In a further non-limiting configuration, probe 30 (See also FIG. 2) can be positioned at an inlet 31 of tow entrance 12. In this configuration, tow entrance 12 can be an elongated member sized sufficiently to accept incoming tow. Entrance 12 can be tubular, or have other cross-sectional shape to accept the entering tow to be coated. In this regard, while it is possible to coat a single tow as schematically illustrated, it should be appreciated that tow entrance 12 and reactor 10 can be configured to process numerous strands of tow in parallel as desired. Positioning of probe 30 at inlet 31 to tow entrance 12 helps to make sure that any marker gas detected at probe 30 is flowing sufficiently away from the reactor, rather than just being detected as part of a possible eddying of flow around marker gas inlet 26.

Further, the downstream positioning of the exit side detection probe 32 means that probe 32 is positioned away from coater 10 with respect to marker gas inlet 28. In this regard, and in similar manner to the inlet side, probe 32 can be positioned near an outlet 33 of tow exit 14. In this configuration, tow exit 14 can be an elongated member sized sufficiently to accept exiting coated tow. Exit 12 can also be tubular, or can have other cross-sectional shape to accept the exiting coated tow. In this regard, while it is possible to coat a single tow as schematically illustrated, it should be appreciated that tow entrance 12 and reactor 10 can be configured to process numerous strands of tow in parallel as desired. Positioning of probe 32 at outlet 33 from tow exit 14 helps to make sure that any marker gas detected at probe 32 is flowing sufficiently away from the reactor, rather than just being detected as part of a possible eddying of flow around marker gas inlet 28.

In the configuration described above, the marker gas detection probes 30, 32 detect for marker gas, and when they do detect marker gas, this is a good indication that flow from marker gas inlets 26, 28 is flowing away from the reactor as desired.

In an alternative configuration, probes 30, 32 could be positioned between marker gas inlets 26, 28 and the reactor 10. In this configuration, detection by the probes 30, 32 of no marker gas would be a favorable indication that no flow was traveling from the marker gas inlets 26, 28 toward the reactor 10. Thus, in this configuration, the marker gas would be used to allow confirmation that no air with accompanying marker gas is flowing from inlets 26, 28 toward reactor 10.

A control unit 34 can be provided and communicated with probes 30, 32 as well as, in this non-limiting configuration, pump 24. Control unit comprises or has access to storage to store control software configured to receive input from probes 30, 32. Further, control unit 34 is configured with this software to change operation of the coating process, for example by changing operation of pump 24, when no marker gas is detected by either or both of probes 30, 32 in which case it can be deduced that fluid or gas flow in the entrance 12 and/or exit 14 is flowing in the wrong direction and oxygen can be entering the coater 10. In such an event, pump 24 can be operated to increase pressure in the coater sufficiently that flow changes to the intended direction, and marker gas is detected at probes 30, 32. In the non-illustrated embodiment wherein the sensors are positioned toward the coater from the marker gas inlets 26, 28, these steps can be taken when marker gas is detected.

Ideally, coater 10 is operated with a slight vacuum with respect to ambient conditions surrounding the coater. This helps to keep process gases from escaping into the surrounding area and creating hazardous conditions. Further ideally, and as mentioned above, it is desirable to not have ambient air enter the coater, as this creates undesirable oxygen levels in the coating.

The positioning of marker gas inlets 26, 28 and probes 30, 32 allows detection of the flow conditions at the tow entrance 12 and tow exit 14. If probes 30, 32 detect marker gas, this means that the marker gas flow from inlets 26, 28 is at least partially moving away from the coater, and therefore that ambient air is not leaking into the coater. If, on the other hand, either or both probes 30, 32 do not detect the presence of marker gas, this means that the marker gas is flowing entirely toward the coater, and therefore that it is likely that some ambient air is also flowing in this direction. When this is the case, an increase in the pressure within the coater can help to restore flow conditions as desired and keep ambient air from leaking into the coater. In such a case, the process parameters such as tow coater pressure or nitrogen purge flow needs to be adjusted to assure that some nitrogen purge gas or marker gas is coming out of the tow entrance or exit based on the He detection system. Thus, when either or both of probes 30, 32 detects no marker gas, operation of vacuum pump 24 can be modified, or some other steps taken, to mildly increase pressure within the coater. Control unit 34 can be programmed and configured to operate in this manner.

The marker gas can be entirely a gas that can be detected by probes 30, 32, or can be a carrier gas doped with a marker gas fraction that can be detected by probes 30, 32. In one non-limiting configuration, marker gas can be a nitrogen carrier gas doped with helium. In this regard, a concentration of helium in the carrier gas can be between about 1 ppm and about 1000 ppm, and these limits can be selected to be reliably detected while minimizing the use of potentially costly helium. In both cases, the gases used are inert with respect to the coating process to limit impact on the composition of the coating. In one non-limiting configuration, the marker gas can be any gas that would be specific to the gas fed to inlets 26, 28, and that can be detected by a sensor. In one non-limiting configuration, this marker gas is helium, and the sensors are sensors configured to detect small concentrations of helium. Other configurations are possible within the broad scope of the disclosure.

The marker gas is referred to herein in places as being a purge gas. This is so because the gas can be introduced to the marker gas inlets at a flow rate and pressure sufficient to help keep ambient air away from the open ends of the coater. In this regard, marker gas can suitably be fed to the marker gas inlets at a flow rate of between 0.1 standard liter per minute (SLM) and 10 SLM and at a pressure of between 14.7 psi and 15.7 psi.

Typical fiber tow to be coated in this process can be silicon carbide fiber tows, for example. Other suitable fiber tows include carbon (C), silicon oxycarbide (SiOC), silicon nitride (Si₃N₄), silicon carbonitride (SiCN), hafnium carbide (HfC), tantalum carbide (TaC), silicon borocarbonitride (SiBCN), and silicon aluminum carbon nitride (SiAlCN), and alumina (Al₂O₃).

Typical process gas for use in CVD coating of fiber tow as disclosed herein can be process gas selected to deposit boron nitride coatings on the fiber tow. These gasses include, without limitation, boron trichloride (BCl₃) and ammonia (NH₃) mixed with inert gas such as nitrogen (N₂), hydrogen (H₂), argon (Ar), or mixtures thereof.

The relative pressures with respect to ambient and the coater can be, for example, 14.7 psi at room temperature. Inside coater 10, this pressure can be kept slightly lower, for example between 12.7 psi and 14.7 psi, to prevent escape of process gas out of the coater. Temperature within the coater will be between 900° C. and 1500° C.

FIG. 2 is an enlarged portion of FIG. 1 and shows in greater scale one of the marker gas inlets 26, 28 and the possible directions in which the marker gas can flow. As shown, marker gas (schematically illustrated at arrow 36) can be introduced into marker gas inlet 26, 28 and, when this gas flow reaches tow entrance 12 and/or tow exit 14, it can flow in either or both directions shown, that is, in a direction 38 toward coater 10, and/or in a direction 40 that is away from coater 10. If flow is in direction 38 only, then no marker gas will reach probe 30-32, which will then signal the possibility that air is leaking into coater 10. If any flow of marker gas is detected in direction 40, then this is conclusive evidence that marker gas is flowing out of the coater 10, and therefore that ambient air is not leaking into coater 10. The direction of flow of marker gas introduced into inlet 26, 28, can be determined by a combination of the relationship between pressure in the coater and surrounding ambient pressure. In this regard, this relationship can be adjusted by adjusting the pressure in the coater. In addition, the relationship can be determined by a volume of flow through inlets 26, 28.

It should be appreciated that in addition to the marker gas sensors as disclosed herein, one or more oxygen sensors can be added to the system to supplement the ability to monitor for oxygen in the reactor and in some instances be able to reduce the number of relatively more expensive helium sensors that are needed.

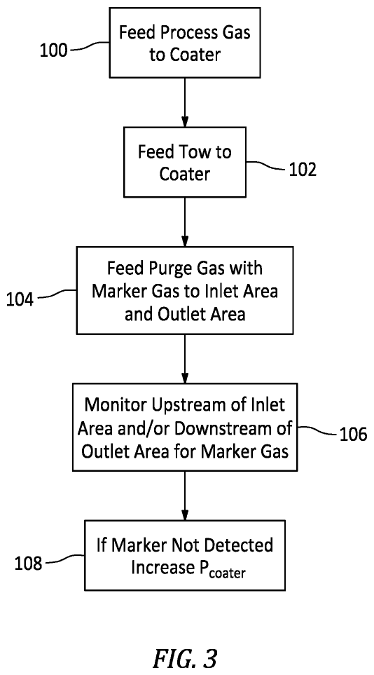

FIG. 3 schematically illustrates a process in accordance with the present disclosure which can be used to provide in situ monitoring of the inlet and outlet of a coater 10 as disclosed herein. As shown, the process can start with the feeding of process gas into a coater as shown at step 100. Once the process gas is in place, the coating process can be started by feeding the fiber tow to coater 10 as shown in step 102. Coater 10 can be kept at process conditions suitable to have the process gasses make a deposit of a process gas materials on the fiber tow, thereby coating such fiber tow materials with a coating derived from the process gasses.

While the coating is conducted, a marker gas can be fed to inlets 26, 28 as shown in step 104. As discussed above, this marker gas reaches entrance 12 and exit 14, and can flow in either or both of away from coater 10, and toward coater 10. This step is schematically illustrated at 104.

Next, in step 106, probes 30, 32 can be used to monitor upstream of the inlet 26 and downstream of the inlet 28, for example at inlet 31 and outlet 33, for the presence of marker gas. As long as marker gas is detected, the process can proceed in a normal and steady state condition. However, the absence of marker gas at the monitored areas of inlets 26 and 28, for example at inlet 31 and outlet 33, means that the marker gas is flowing entirely toward the coater, and therefore it is possible or likely that ambient air is also flowing toward the coater.

If this is the case, then in step 108, steps can be taken to increase pressure within the coater. This can be done by increasing purge flow rate of the marker gas if desired, or by decreasing the pressure within the coater for example by increasing operation of vacuum pump 24, or the like.

The system and method disclosed herein offer a continuous atmospheric pressure CVD tow coater process with in-situ air leak monitoring using a He detection system. The proposed process can improve the performance and lifetime of ceramic matrix composite (CMC) materials because it can reduce detrimental oxygen content in the interface coatings by avoiding ambient air leaking into the tow coater.

The use of the terms “a” and “an” and “the” and similar references in the context of description (especially in the context of the following claims) are to be construed to cover both the singular and the plural, unless otherwise indicated herein or specifically contradicted by context. The modifier “about” used in connection with a quantity is inclusive of the stated value and has the meaning dictated by the context (e.g., it includes the degree of error associated with measurement of the particular quantity). All ranges disclosed herein are inclusive of the endpoints, and the endpoints are independently combinable with each other. It should be appreciated that relative positional terms such as “forward,” “aft,” “upper,” “lower,” “above,” “below,” and the like are with reference to the normal operational attitude of the vehicle and should not be considered otherwise limiting.

Although the different non-limiting embodiments have specific illustrated components, the embodiments of this invention are not limited to those particular combinations. It is possible to use some of the components or features from any of the non-limiting embodiments in combination with features or components from any of the other non-limiting embodiments.

It should be appreciated that like reference numerals identify corresponding or similar elements throughout the several drawings. It should also be appreciated that although a particular component arrangement is disclosed in the illustrated embodiment, other arrangements will benefit from the subject matter disclosed herein.

Although particular step sequences are shown, described, and claimed, it should be understood that steps may be performed in any order, separated or combined unless otherwise indicated and will still benefit from the present disclosure.

The foregoing description is exemplary rather than defined by the limitations within. Various non-limiting embodiments are disclosed herein, however, one of ordinary skill in the art would recognize that various modifications and variations in light of the above teachings will fall within the scope of the appended claims. It is therefore to be understood that within the scope of the appended claims, the disclosure may be practiced other than as specifically described. For that reason the appended claims should be studied to determine true scope and content.

1. A system for chemical vapor deposition coating of fiber tows, comprising:
a coater comprising a housing having a tow entrance and a tow exit and defining an interior space, the coater further comprising a process gas inlet and a process gas outlet;
at least one of an entrance side marker gas inlet at the tow entrance and an exit side marker gas inlet at the tow exit;
at least one of an entrance side detection probe upstream of the entrance side marker gas inlet, and an exit side detection probe downstream of the exit side marker gas inlet, the at least one entrance side detection probe and exit side detection probe being configured to detect marker gas.

2. The system of claim 1, further comprising a pump communicated with the interior space of the coater whereby operation of the pump can be adjusted to adjust pressure in the interior space.

3. The system of claim 1, further comprising a take-off spool for feeding fiber tow to the tow entrance, and a take-up spool for receiving coated fiber tow from the tow exit.

4. The system of claim 1, further comprising a source of marker gas communicated with the at least one entrance side marker gas inlet and exit side marker gas inlet.

5. The system of claim 4, wherein the source of marker gas comprises a source of an inert carrier gas containing a detectable fraction of detectible gas.

6. The system of claim 4, wherein the source of marker gas comprises a source of nitrogen gas dosed with helium.

7. The system of claim 6, wherein the at least one detection probe comprises a probe configured to detect helium.

8. The system of claim 1, further comprising a control unit configured to receive input from the at least one detection probe and, upon receiving input indicating no marker gas detected, configured to operate the coater at a higher pressure in the interior space.

9. The system of claim 2, further comprising a control unit configured to receive input from the at least one detection probe and, upon receiving input indicating no marker gas detected, configured to change operation of the pump to operate the coater at a higher pressure in the interior space.

10. The system of claim 1, wherein the system comprises both of the entrance side marker gas inlet and the exit side marker gas inlet, and both of the entrance side marker gas detection probe and the exit side marker gas detection probe.

11. A method for chemical vapor deposition coating of fiber tows, comprising:
feeding a fiber tow to a tow entrance of a coater comprising a housing defining an interior space;
feeding a chemical vapor deposition process gas to the coater at a process gas inlet such that fiber tow in the coater is coated to produce coated fiber tow;
removing coated fiber tow from a tow exit of the coater; feeding a marker gas to at least one of an entrance side marker gas inlet at the tow entrance and an exit side marker gas inlet at the tow exit; and
monitoring at least one of upstream of the entrance side marker gas inlet, and downstream of the exit side marker gas inlet, for presence of marker gas.

12. The method of claim 11, further comprising adjusting pressure in the coater when the monitoring step does not detect marker gas.

13. The method of claim 11, wherein the monitoring step comprises positioning at least one marker gas detection probe in the at least one of upstream of the entrance side marker gas inlet and downstream of the exit side marker gas inlet; and further comprising feeding output from the at least one marker gas detection probe to a control unit configured to operate the coater at a higher pressure when the output indicates no detection of marker gas.

14. The method of claim 13, further comprising a pump associated with the interior space of the coater, wherein the control unit is configured to change operation of the pump to operate the coater at a higher pressure.

15. The method of claim 11, wherein the marker gas comprises an inert carrier gas dosed with a detectable amount of marker gas.

16. The method of claim 15, wherein the carrier gas is nitrogen.

17. The method of claim 15, wherein the marker gas is helium.

18. The method of claim 11, further comprising removing the process gas from the coater at a process gas outlet of the coater.

19. The method of claim 18, further comprising feeding process gas from the process gas outlet to a scrubber.

20. The method of claim 11, wherein the step of feeding the chemical vapor deposition process gas to the coater is carried out such that pressure inside the coater (P_{coater}) is less than ambient pressure (P_{ambient}) outside the coater (P_{coater}<P_{ambient}).
